(19) United States
(12) Patent Application Publication
(10) Pub. No.: US 2025/0203752 A1
(43) Pub. Date: Jun. 19, 2025

(54) PRINTED CIRCUIT BOARD, METAL-CERAMIC SUBSTRATE AS AN INSERT, AND METHOD FOR MANUFACTURING A PRINTED CIRCUIT BOARD

(71) Applicant: Rogers Germany GmbH, Eschenbach (DE)

(72) Inventor: Andreas Meyer, Speichersdorf (DE)

(21) Appl. No.: 18/849,669

(22) PCT Filed: Mar. 21, 2023
(86) PCT No.: PCT/EP2023/057112

§ 371 Date: Sep. 23, 2024

(30) Foreign Application Priority Data
Mar. 24, 2022 (DE) 10 2022 106 953.2

(51) Int. Cl. H05K 1/02; H05K 1/03; H05K 3/46

(52) U.S. Cl. CPC H05K 1/0204; H05K 1/0306; H05K 3/4605; H05K 2201/0191; H05K 2201/068; H05K 2201/10416

(57) ABSTRACT

Printed circuit board (100) for electrical components (5) and/or conductor paths (4), comprising:
a base body (2) which extends along a main extension plane (HSE), and
an insert (1) which is integrated into the base body (2) in the assembled state,

wherein the insert (1) is a metal-ceramic substrate (10), the metal-ceramic substrate (1) being covered, in particular surrounded, at least partially by an insulating element (8) on a side surface (SF) facing the base body (2) in the assembled state.

### CROSS REFERENCE TO RELATED APPLICATIONS

This application is a National Stage application of PCT/EP2023/057112, filed Mar. 21, 2023, which claims the benefit of German Application No. 10 2022 106 953.2, filed Mar. 24, 2022, both of which are incorporated by reference in their entirety herein.

### BACKGROUND

The present invention relates to a printed circuit board, a metal-ceramic substrate as an insert for such a printed circuit board and a method for the production of a printed circuit board.

Printed circuit boards are sufficiently known from the prior art. Such printed circuit boards serve as carriers for electrical circuits which are formed or composed of conductor paths, electrical components and/or connections. The electrical circuits are preferably formed on one component side of the printed circuit board. Such circuit boards, also known as PCBs (printed circuit boards), are usually made of a plastic, in particular a fiber-reinforced plastic, an epoxy resin and/or a hard paper. The use of such materials proves to be particularly cost-effective and easy to handle during the manufacturing process. However, it has been shown that the aforementioned materials for printed circuit boards have limited thermal conductivity, although this is necessary in order to dissipate heat that emanates from certain electrical components during operation. The insulation capability is also limited, too. With the increasing performance of electronic components, printed circuit boards made from conventional materials are therefore unsuitable for permanently withstanding the stresses arising during operation and providing good insulation properties.

On the other hand, printed circuit boards formed as metal-ceramic substrates are characterized by a high insulation capability and they typically have higher thermal conductivities compared to those of the above-mentioned materials. However, the production of metal-ceramic substrates is more complex and cost-intensive than the production of printed circuit boards made of plastic, epoxy resin and/or hard paper.

Based on the prior art, the present invention sets itself the task of providing printed circuit boards which meet the raised requirements for heat dissipation and, in particular, for insulation capability in the area of the electrical component and, at the same time, can be produced at a lower cost.

### SUMMARY

This task is solved by a printed circuit board as described herein, a metal-ceramic substrate as described herein and a method as described herein. Further examples of embodiments can be found in the the description.

According to a first aspect of the present invention, a printed circuit board for electrical components and/or conductor paths is provided, comprising
a base body extending along a main extension plane, and
an insert which is integrated into the base body in an assembled state,
   wherein the insert is a metal-ceramic substrate and wherein the metal-ceramic substrate is covered, in particular surrounded, at least partially by an insulating element on a side surface facing the base body in the assembled state.

### BRIEF DESCRIPTION OF THE DRAWINGS

Further advantages and features result from the following description of preferred embodiments of the object according to the invention with reference to the attached figures. Individual features of the individual embodiments can be combined with each other within the scope of the invention.

It is shown:

FIG. 1: a schematic representation of a printed circuit board according to an embodiment in a plan view (top) and a sectional view (bottom);

FIG. 2: an insert according to an embodiment;

FIG. 3 an insert according to an embodiment;

FIG. 4 an insert according to an embodiment;

FIG. 5 an insert according to an embodiment; and

FIG. 6 an insert according to an embodiment.

### DETAILED DESCRIPTION

Compared with the printed circuit boards known from the prior art, it is more preferably provided that the base body of the printed circuit board is not formed entirely from one of the conventional materials, such as plastic, hard paper and/or epoxy resin, but that a section of the printed circuit board is formed at least from a metal-ceramic substrate. In particular, the metal-ceramic substrate is embedded or inserted into the base body of the printed circuit board in order to provide increased thermal conductivity locally. This makes it possible, for example, to insert or embed metal-ceramic substrates as inserts in the printed circuit board in areas where increased heat generation is to be expected. For example, the insert is arranged in a direction perpendicular to the main extension plane below the electrical or electronic component that is responsible for increased heat generation during operation. At the same time, it is possible to manufacture the majority of the base body from a material such as a plastic, in particular a fiber-reinforced plastic, epoxy resin or a hard paper, which is inexpensive and easy to process.

In particular, it is provided that the insulating element does not surround any component. In other words, if a component is mounted or can be mounted on the insert, this component is arranged at least on a side surface that is free from being covered by the insulating element. Preferably, the insulating element is arranged in a direction parallel to the stacking direction below the electrical component (without being in contact with the component) and/or on a top side of the ceramic element facing away from the ceramic element, which is used as a bonding or contact surface for the component and thus not on the side surface that is essentially covered by the insulating element. The electrical component is preferably free from insulating elements, i.e. it is not in contact with the insulating element of the side surface of the insert.

Preferably, the insulating element is distinct from the base body. For example, the base body differs from the insulating element in terms of its physical properties, for example because they are different materials. In the inserted state, the base body, the insert and the insulating element can therefore be distinguished from each other as individual elements. Furthermore, it is preferably provided that the insulating element does not have any adhesive or bonding effect. In other words, the insulating element is unsuitable for forming an independent material bonded connection with the base body. An additional, preferably separate, adhesive element or a positive and/or frictional locking means is provided for fixing.

Preferably, the metal-ceramic substrate is coated with the insulating element, i.e. a coating is formed.

Furthermore, it is preferably conceivable that the component metallisation is essentially free from a structure and forms a continuous metal layer without any electrically insulating discontinuity. It is also provided that the insulating element is arranged exclusively in the area above the pullback, i.e. above the section of the ceramic element protruding from the component metallization, and not between two metal sections of the component metallization separated from each other, for example by an isolation trench, if the component metallization has a structure.

In particular, it proves to be especially advantageous if the side surface of the metal-ceramic substrate is at least partially, preferably completely, surrounded or sheathed by an insulating element. Due to the lateral arrangement of the insulating element, this insulating element is arranged between the base body and the metal-ceramic substrate in the assembled state and supports or reinforces the insulating effect of the metal-ceramic substrate used, in particular the avoidance of creepage or air gaps along the surface of the ceramic between the component and backside metallization. This sometimes makes it possible to reduce the first length at which the ceramic element protrudes in order to form a pullback in relation to the component metallization, or even to dispense with the formation of a pullback altogether. In this case, the insulating element provides the necessary insulation. This is particularly advantageous because a prepreg material (insulator) must fill the cavities formed by the pullback when laminating the printed circuit board. However, a corresponding pullback creates the risk of insulation problems due to creepage or air gaps on the ceramic surface between the component metallization and the backside metallization. This can be avoided with a reduced pullback. If conductor paths are formed in the base body, the insulating element can also be used for further insulation from the base body. In this case, the insulating element can extend over the entire height of the insert or it is interrupted, for example, at least partially along a height extension of the insert that runs perpendicular to the main extension plane, i.e. along a stacking direction of the metal-ceramic substrate.

For example, it is also conceivable that the insulating element extends in a direction perpendicular to the main extension plane by means of a first height, wherein the ratio of the first height to a total height of the insert, measured in the same direction, has a value between 0.4 and 1, preferably between 0.6 and 1 and more preferably between 0.7 and 1. In this way, for example, an annular, circumferential insulating element is formed, which can be used in specific areas for insulation protection between the component metallization and the backside metallization. For example, it is conceivable that the insulating element extends as an annular sheathing at the height of the ceramic element of the metal-ceramic substrate and provides insulation protection between the component metallization and the backside metallization in this area. Furthermore, it is conceivable that the first height in this case has a value by which the ratio of a first thickness of the ceramic element measured perpendicular to the main extension plane to the first height of the insulating element has a value between 0.5 and 2, preferably between 0.8 and 1.5 and more preferably between 1.1 and 1.5. It is preferably provided that the insulating element is part of the insert.

Furthermore, it is preferably provided that the insulating element is a coating on the side surface and/or forms a cover body or encapsulation body which is produced, for example, by a casting, injection, spraying, dipping or injection molding process. Preferably, the material used for the insulating element is free from ceramic and/or comprises ceramic particles that are incorporated into a corresponding plastic matrix. Preferably, it is provided that the insulating element is essentially formed from a plastic, an epoxy resin and/or a hard paper, which more preferably corresponds to that from which the base body is formed.

It is preferably provided that the metal-ceramic substrate has a ceramic element, a component metallization and preferably a backside metallization, wherein the insulating element surrounds the component metallization and/or the ceramic element at least partially, preferably completely, on the side facing the base body in the assembled state. It is conceivable that the insulating element only surrounds the component metallization and/or the ceramic element and/or the backside metallization, i.e. the insulating element only surrounds a specific subregion in each case, which is defined by one or more components of the metal-ceramic substrate. It is also conceivable that the insulating element only encases or surrounds the component metallization and the ceramic element and/or only the ceramic element and the backside metallization. In particular, it is possible to increase the insulation between the insert and the base body by arranging the insulating element around the circumference or on the side surface of the metal-ceramic substrate in an application-specific manner. It is also conceivable that the insulating element extends from the area of the component metallization to the area of the ceramic element and/or to the area of the backside metallization without completely covering the component metallization, the ceramic element and/or the backside metallization on their side surfaces.

When surrounding or sheathing, the metal-ceramic substrate is preferably surrounded by an enclosed curve of the insulating element in a plane that runs parallel to the main extension plane.

Preferably, it is provided that the ceramic element is formed between the component metallization and the backside metallization. The component metallization, the ceramic element and the backside metallization are arranged on top of one another along a stacking direction perpendicular to the main extension plane. In particular, it is provided that the metal-ceramic substrate consists of component metallization, ceramic element and backside metallization. Essential components of the metal-ceramic substrates are an insulating layer, which is preferably made entirely of a ceramic, and at least one metal layer bonded to the insulating layer. Due to their comparatively high insulation strength, insulating layers made of ceramic have proven to be particularly advantageous in power electronics. By structuring the metal layer, conductor paths and/or connecting areas for the electrical components can then be realized. It is preferable provided that the component metallization is not structured, but forms a closed surface when the metal-ceramic substrate is provided as an insert,. The prerequisite for providing such a metal-ceramic substrate is a permanent bonding of the metal layer to the ceramic layer. In addition to a so-called direct metal bonding method, i.e. a DCB or DAB method, bonding via an active soldering process, a thick film layer method, diffusion bonding and/or hot isostatic bonding is also conceivable.

Copper, aluminum, molybdenum, tungsten and/or their alloys, such as CuZr, AlSi or AlMgSi, as well as laminates such as CuW, CuMo, CuAl and/or AlCu or MMC (metal matrix composite), such as CuW, CuMo or AlSiC, are conceivable as materials for the metal layer or metallization. Furthermore, it is preferably provided that the metal layer or metallization on the manufactured metal-ceramic substrate is surface-modified, in particular as component metallization. A surface modification could be, for example, sealing with a precious metal, in particular silver; and/or gold, or (electroless) nickel or ENIG (“electroless nickel immersion gold”) or edge encapsulation on the metallization to suppress crack formation or expansion. For example, the metal of the component metallization also differs from the metal of the backside metallization.

Preferably, the ceramic element comprises Al2O3, Si3N4, AlN, an HPSX ceramic (i.e. a ceramic with an Al2O3 matrix comprising an x-percentage of ZrO2, for example Al2O3 with 9% ZrO2=HPS9 or Al2O3 with 25% ZrO2=HPS25), SiC, BeO, MgO, high-dense MgO (>90% of the theoretical density), TSZ (tetragonally stabilized zirconium oxide) as material for the ceramic. It is also conceivable that the ceramic element is formed as a compound or hybrid ceramics, in which several ceramic layers, each of which differs in terms of its material composition, are arranged on top of one another and joined together to form a ceramic element in order to combine various desired properties.

In particular, it is provided or preferably provided that, when the component metallization or its side surface is sheathed, the insulating element ends flush with the ceramic element in a direction parallel to the main extension plane and or protrudes with respect to the ceramic element. Alternatively, it is also conceivable that the ceramic element protrudes with respect to the insulating element in a direction parallel to the main extension plane.

Preferably, on the component side, an upper side of the component metallization facing away from the ceramic element is arranged below a top side of the base body when viewed in the assembled state in the stacking direction. In other words, on the component side, the top side of the component metallization is formed to recess into the course of the top side of the base body when the insert is integrated into the printed circuit board. For example, in the embedded state of the insert, the top side of the component metallization has a recess depth of 10 μm to 200 μm relative to the top side of the base body, preferably between 10 μm and 150 μm and more preferably between 10 μm and 100 μm. Alternatively or additionally, it is provided that on the back side, an underside of the backside metallization facing away from the ceramic element has a recessed course relative to the bottom side of the base body, preferably with one of the recess depths mentioned above. The insert is thus smaller than the thickness of the base body when viewed in the stacking direction, and it is also preferably provided that the top side and bottom side of the insert both do not end flush with the top side and bottom side of the base body. It is conceivable that the insert only ends flush with the bottom side of the base body on the back side of the printed circuit board.

Preferably, it is provided that the insulating element covers at least partially a side of the component metallization facing away from the ceramic element. In other words, the top side of the metal-ceramic substrate is also covered at least partially with the insulating element. For example, it is conceivable that a peripheral section or peripheral region, i.e. an outer peripheral region in a plane parallel to the main extension plane, of the component metallization or the top side of the component metallization is additionally covered with the insulating element in order to further insulate the component metallization from the base body of the printed circuit board. The peripheral region is preferably understood to be the surface formed at the outer edge, which forms up to 15%, preferably up to 10% and more preferably up to 5% of the total surface area on the outer side of the component metallization facing away from the ceramic element. It is also conceivable that the component metallization covers more than 10%, preferably more than 30% and more preferably more than 50% of the top side of the component metallization, also outside the peripheral region, and only allows access to the component metallization in certain areas in order to further isolate the component metallization from the base body and at the same time ensure sufficient access for the connection of a component metallization. It is also conceivable that conductor paths run via the insulating element in order to realize an electrical joining between a subsection of the base body and the component metallization in this way.

Preferably, it is provided that the ceramic element of the metal-ceramic substrate protrudes by a first length in a direction parallel to the main extension plane relative to the component metallization of the metal-ceramic substrate. A corresponding protruding area, which is also known as a pullback, serves in particular for the electrical insulation of component metallization and backside metallization and can preferably also be used as a form-fit means when inserting or fixing the insert in or on the base body of the printed circuit board. It is conceivable that the component metallization and/or the ceramic element and/or the backside metallization is covered with an insulating element with an essentially constant width, so that the metal-ceramic substrate insert sheathed with the insulating element also has a corresponding protrusion at the hight of the ceramic element, which is due to the ceramic element protrusion by a first length. The width of the insulation element is dimensioned in a direction parallel to the main extension plane.

Preferably, it is provided that the insert and/or the insulating element interacts with the base body in a form-fit manner in a direction running perpendicular to the main extension plane and is preferably material bonded to the base body. This creates a particularly stable and permanent connection between the base body and the insert, which is particularly advantageous because, due to the different thermal expansion coefficients for metal, ceramic and epoxy resin, joining via a frictional method generally does not result in a permanent bond. Accordingly, a desired form fit is realized by a corresponding modulation depth of the side surface, which prevents the metal-ceramic substrate from changing its geometric shape under the influence of temperature and thus impairing the printed circuit board.

If desired, a frictional connection between the insert and the base body can also be achieved.

Preferably, the form fit acts in both possible directions, which are perpendicular to the main extension plane of the base body. It is also conceivable that further inserts are arranged in the base body in addition to the insert. It is also conceivable that the insert ends flush with the base body only on the component side and the backside of the metal-ceramic substrate is enclosed by the base body. In other words, the metal-ceramic substrate or the insert is embedded or inserted into a recess in the base body of the printed circuit board. This also results in a form fit parallel to the main extension plane.

In particular, it is provided that the metal-ceramic substrate and the base body are designed in such a way that their thermal expansion coefficients are as similar as possible. In other words, a difference in the thermal expansion coefficient of the insert and the base body is kept as small as possible. For this purpose, for example, a corresponding thickness of the ceramic element in the metal-ceramic substrate is set. It is also conceivable that a stabilizing layer is provided to adjust the thermomechanical expansion coefficient or that several metal layers and/or different metallizations (e.g. component metallizations and back metallizations are made of different metals or materials) are used to ensure the desired adjustment in an appropriate manner. This can ensure that no significant mechanical stresses arise between the base plate and the metal-ceramic substrate due to expansion during operation, which could lead for example to crack formation. Preferably, it is also conceivable that different ceramic layers are used in a metal-ceramic substrate with multiple ceramic layers.

It has proven to be advantageous if, in addition to the form fit, a material bond is created between the side surface of the insert and the base body.

Preferably, it is provided that, for example, the component metallization and/or the insulating element and/or the ceramic element provide a corresponding side profiling, in particular with a corresponding modulation depth. The side surface of the insulating element and/or the component metallization and/or the ceramic element and/or the metal-ceramic substrate can thereby be curved, inclined, stepped, nose-shaped and/or otherwise shaped in order to cause the form fit in a direction perpendicular to the main extension plane.

Preferably, it is provided that in order to form the cooperation via form-fit, the insulating element is profiled on a side surface that does not run parallel to the main extension plane. In particular, the profiling is carried out on a side that faces the base body in the assembled state and is in contact with the base body.

Preferably, it is provided that the insulating element has a width in a direction parallel to the main extension plane which has a value between 10 μm and 800 μm, preferably between 150 μm and 500 μm and more preferably between 250 μm and 350 μm. This provides a comparatively thin insulating layer which has been found to be sufficient to provide additional significant insulation protection between the component metallization and the backside metallization, in particular when the first length is less than 80 μm, preferably less than 50 μm and more preferably less than 25 μm.

In particular, it is provided that the insulating element has a width averaged along the first height of the insulating element in a direction dimensioned parallel to the main extension plane, which has a value greater than 250 μm, preferably greater than 350 μm and more preferably greater than 500 μm. It has been shown that such wide insulating elements are suitable for forming an effective and additional insulating layer. In particular, such a wide insulating element also allows thinner ceramic elements to be realized, preferably with thicker component metallization and backside metallization.

It is preferably provided that the component metallization and/or the backside metallization are thicker than the thickness of the insulating element. This places higher demands on the insulating element, in particular with regard to the electrical insulation strength between the component metallization and the backside metallization.

Preferably, it is provided that, measured in a direction perpendicular to the main extension plane, the ceramic element has a first thickness, the base body has a second thickness and the component metallization has a third thickness, wherein a ratio between the first thickness and the second thickness and/or a ratio between the first thickness and the third thickness has a value between 0.01 and 0.3, more preferably between 0.01 and 0.2 and most preferably between 0.01 and 0.15. This makes it advantageous to use a comparatively thin ceramic. In this case, it proves to be particularly advantageous if the insulating element surrounds the side surfaces of the metal-ceramic substrate in order to increase the insulation.

A further aspect of the present invention is a metal-ceramic substrate that is used as an insert for a printed circuit board according to the present invention, wherein the insert is surrounded at least partially by an insulating element on a side surface that does not run parallel to the main extension plane. All the properties and advantages described for the printed circuit board result analogously for the metal-ceramic substrate used as the insert and vice versa.

In particular, it is completely unusual in the prior art to cover the side surfaces of the metal-ceramic substrate, especially at the hight of the ceramic element, with an insulating element. Preferably, it is provided that the insert is completely surrounded by an insulating element on the non-parallel side surfaces. In particular, such an insert can be unscrupulously inserted into any base body of a suitable size. In particular, the insulating element is not self-adhesive. This simplifies handling of the insert, especially when inserting it into the base body.

Furthermore, it is provided that the metal-ceramic substrate is provided as an insert together with the insulating element and is installed together with the insulating element bonded to the metal-ceramic substrate. It is thereby conceivable that the insulating element itself is adhesive and that a protective cover is provided, which is more preferably only removed when the insert is to be inserted into the base plate.

In particular, it is provided that the insulating element surrounds the metal-ceramic substrate in an enclosed manner, at least in a height section of the metal-ceramic substrate. For example, the insulating element surrounds the component metallization, the ceramic element and/or the backside metallization in the form of a strip. It is also conceivable that only a subsection or a height section of the component metallization, the ceramic element and/or the backside metallization is surrounded or covered by the insulating element. In this case, the strip-shaped course of the insulating element is preferably in an enclosed manner in a plane parallel to the main extension plane.

A further object of the present invention is a method for the production of an insert, which is provided for a printed circuit board according to the invention comprising:
Providing a metal-ceramic substrate having a main extension plane,
covering at least partially the metal-ceramic substrate with an insulating element, and
inserting the insert with the insulating element into the base body.

All the advantages and properties described for the printed circuit board apply analogously to the method and vice versa.

Preferably, it is provided that the base body is made of a different material than the insert. In particular, it is provided that the base body is essentially free from ceramic or does not provide a ceramic element as an insulating layer or stabilizing layer. Preferably, the base body contains less than 10 weight percent, more preferably less than 5 weight percent and most preferably less than 3 weight percent ceramic.

In particular, it is thereby provided that a proportion of the metal-ceramic substrate in the proportion of the printed circuit board is less than 50%, preferably less than 30% and more preferably less than 15%. Furthermore, it is provided that the insert extends from the component side of the base board to the backside of the base body of the printed circuit board. In other words, the insert ends essentially flush with the base body in a direction perpendicular to the main extension plane on both sides, i.e. on the component side and on the backside. In particular, a permanent bond between the metal-ceramic substrate and the base body is formed by the form fit between the base body and the metal-ceramic substrate, which prevents the insert from detaching from the printed circuit board.

According to a preferred embodiment, it is provided that in order to form the cooperation via form-fit
the metal-ceramic substrate is profiled on a side surface that does not run parallel to the main extension plane and/or
a ceramic element of the metal-ceramic substrate protrudes by a first length in a direction parallel to the main extension plane with respect to a component metallization and/or the backside metallization of the metal-ceramic substrate,
   wherein the metal-ceramic substrate is surrounded by an insulating element. In this case, the side profiling can be supported by the insulating element or can be maintained with an insulating element having a constant width via the entire height of the insert.

For example, it is provided that a side surface, in particular a side surface of the component metallization and/or backside metallization and/or the insulating element is concave and/or convexly curved. Alternatively, it is also conceivable that the component metallization and/or the insulating element is stepped. In particular, it is provided that the base body engages in the recessed or protruding courses on the side surfaces of the insulating element, the component metallization and/or the back metallization, so as to cause the form fit in a direction or both directions that run perpendicularly to the main extension plane. For example, it is conceivable that the outermost edge of the component metallization and/or the insulating element is stepped, in particular stepped in such a way that the open area of the step is formed on the side facing the component side and/or the backside. In a corresponding manner, a component can be arranged on the component metallization in such a way that the heat spread is completely absorbedby the component metallization, considering an isotropic transport of the heat. The sections of the component metallization that do not contribute to heat transport in any case are removed in this stepped course and replaced by the base body. Preferably, a protruding section of the ceramic element is used in order to form the form fit. In particular, this is the section known as the pullback, which provides sufficient insulation between the component metallization and the backside metallization.

Preferably, it is provided that the first length has a value between 1 μm and 200 μm, preferably between 20 μm and 100 μm and more preferably between 25 μm and 60 μm. More preferably, the first length relates to a protrusion with which the ceramic element protrudes in a direction parallel to the main extension plane with respect to the insulating element which, for example, surrounds the component metallization.

It has been shown that an effective form fit can already be achieved through appropriate dimensioning and that the additional insulating effect of the material from which the base body of the printed circuit board is formed also ensures electrical insulation between the component metallization and the backside metallization. This comparatively very small protruding section of the ceramic element, i.e. this comparatively small so-called pullback, enables the insert, i.e. the metal-ceramic substrate, to be integrated into the base body of the printed circuit board in the most space-saving manner possible. Preferably, it is provided that the metal-ceramic substrate, in particular with the insulating element, has a maximum expansion in a plane dimensioned parallel to the main extension plane, which has a value between 1 mm and 200 mm, preferably between 4 mm and 60 mm and more preferably between 6 mm and 30 mm. This provides comparatively small-sized inserts that can be used as required to locally increase the thermal conductivity in the printed circuit board. In particular, a comparatively large number of individual inserts can be provided from a master card. Such a master card is defined by the format immediately after bonding the component metallization to the backside metallization, which is done via a corresponding bonding process.

It is also conceivable that the first length also has a negative value. In this case, the component metallization and/or the backside metallization and/or the insulating element surrounding the component metallization and/or the backside metallization protrude with respect to the ceramic element in a direction parallel to the main extension plane. The absolute value of the first length can have the above-mentioned values.

In particular, it is provided that the side surface is profiled, i.e. has such a side profiling, that a modulation depth or height is set which has a value between 1 μm and 200 μm, preferably between 20 μm and 100 μm and more preferably between 25 μm and 60 μm. The modulation depth or height is to be understood as a deviation, measured in a direction parallel to the main extension plane, from an imaginary, cylindrical outer course that is assigned to a narrowest point of the metal-ceramic substrate (measured in planes parallel to the main extension plane). The imaginary cylindrical outer course extends perpendicular to the main extension plane. If the modulation depth is formed by a ceramic element protruding from the component metallization and/or backside metallization and/or the insulating element, the modulation depth can correspond to the first length. It is also conceivable that the modulation depth is caused by the component metallization and/or the ceramic element protruding relative to the backside metallization in a direction parallel to the main extension plane. For example, it is also conceivable that the side surface in the area of the ceramic element has a course that is inclined with respect to the stacking direction (in other words, the top side and the bottom side of the ceramic element have different diameters or dimensions). In particular, the above applies analogously to the modulation depth of the side profiling of the insulating element.

For example, it is conceivable that the course of the side surface or side surfaces in the area of the component metallization and/or backside metallization extends parallel to the stacking direction (i.e. the cross-section of the component metallization and/or backside metallization is essentially constant in the area of the component metallization or backside metallization when viewed in the stacking direction). The modulation depth is then preferably realized by a step at the height of the ceramic element and/or by a corresponding geometry of the insulating element. The modulation depth can be thereby created by profiling or modulation in the area of the ceramic element and/or the insulating element, wherein the profiling can be continuous in the stacking direction via the thickness of the ceramic element or the insulating element or discrete or abrupt at the height of the ceramic element.

Furthermore, it is conceivable that the insert has one or more protrusions which protrude in a direction parallel to the main extension plane with respect to the general course of the outer circumference of the insert. This, preferably nose-shaped, protrusion can advantageously provide an additional form fit in the circumferential direction along the outer circumference, which supports a rotationally fixed arrangement in the base body. It has advantageously been shown that such a protrusion is created by cutting the metal-ceramic substrate out of a master card using laser light and/or water cutting. Due to the constant width of the insulating element, this protrusion is then also formed on the insert with the insulating element.

Preferably, it is provided that the metal-ceramic substrate has a round profile or a rounded corner in the main extension plane. A corresponding design of the cross-section of the insert in a plane that runs parallel to the main extension plane proves to be advantageous in particular because it can reduce a notch effect on the base body of the printed circuit board. This in turn can extend the service life of the printed circuit board with insert.

Preferably, the metal-ceramic substrate is provided with a ceramic element, wherein a component metallization is bonded to the ceramic element, wherein
a stabilizing layer, for example in the form of a further ceramic element, is provided or formed, wherein a metallic intermediate layer is arranged between the ceramic element and the stabilizing layer, and/or
the component metallization and/or the backside metallization comprises a first metal layer and/or a second metal layer, wherein the first metal layer and the second metal layer are arranged on top of one another.

In particular, it is possible to influence the thermal expansion coefficient of the insert by designing the metal-ceramic substrate accordingly in order to adapt it to the coefficient of thermal expansion of the base body. For example, it is conceivable to design the stabilizing layer from a different material or to dimension it accordingly. The thickness of the ceramic element can also be used to optimize the thermomechanical expansion coefficient of the insert in such a way that mechanical stresses between the base body and the insert are reduced. Preferably, the first metal layer differs from a second metal layer with respect to a graining, wherein preferably a graining in the first metal layer is smaller than a graining in the second metal layer and/or most preferably a thickness of the first metal layer is thinner than a second metal layer. Furthermore, it is conceivable that a thickness of the component metallization differs from a thickness of the backside metallization. This makes it advantageously possible to influence a height position of the ceramic element within the base body of the printed circuit board and in particular to ensure that the insulating ceramic element is arranged offset towards the backside and away from the component side in the base body or vice versa.

Furthermore, it is envisaged that profiling of a side surface that does not run parallel to the main extension plane and/or realization of a ceramic element on the metal-ceramic substrate that protrudes in a direction parallel to the main extension plane with respect to the component metallization and/or the backside metallization is provided. In particular, it is conceivable that a profiling and/or an exposure is carried out, for example by etching, by mechanical processing, for example by milling, by processing with laser light and/or by a jet of water.

Preferably, it is provided that a component side and/or backside running essentially parallel to the main extension plane is covered with a protective layer or resist layer and then the side surface is profiled and/or the ceramic element is partially exposed by means of an etching medium. In this way, a desired profiling of the side surface and the exposure of a laterally protruding section of the ceramic element is easily realized by means of a simple etching process. The side surfaces are then covered, at least partially, preferably completely, with an insulating element. In particular, it is provided that the insert is cut out of a metal-ceramic substrate provided as a master card.

Furthermore, it is conceivable that the side surfaces of the inserts are burnished or polished before insertion into the base body.

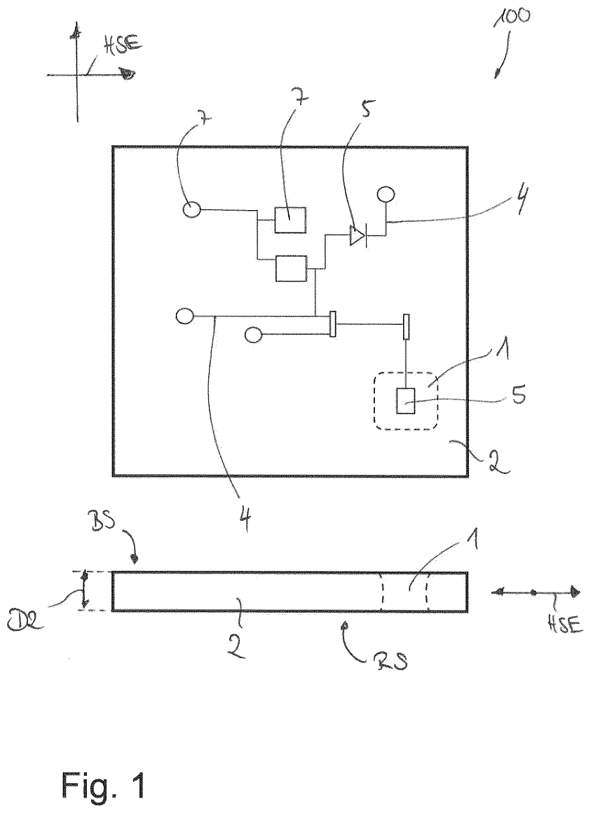

In FIG. 1, a printed circuit board 100 according to a first preferred embodiment of the present invention is shown in a top view (above) and in a sectional view (below). Such printed circuit boards 100 serve in particular as carriers for circuits formed by electrical or electronic components 5, connections 7 and/or conductor paths 4. The electrical or electronic components 5, the conductor paths 4 and/or the connections 7, for example in the form of soldering surfaces (pats) or soldering eyes, are preferably arranged or bonded to a component side BS of the printed circuit board 100. For a particularly cost-effective production of such printed circuit boards 100, it has become established to use plastics, in particular fiber-reinforced plastics, epoxy resin and/or hard paper as materials for a base body 2, which extends essentially along a main extension plane HSE and to whose component side BS the connections 7, electronic components 5 and/or conductor paths 4 are formed or bonded.

Due to the constant further development in the field of electronics, in particular with regard to the performance of the electronic components 5, it has been shown that the materials used for the base body 2 cannot permanently withstand the new challenges, in particular with regard to the heat generated during operation. This is due in particular to the fact that the aforementioned materials for the base body 2 of a printed circuit board 100 have a comparatively low thermal conductivity, thus the heat generated by the electrical components during operation cannot be dissipated to a sufficient extent.

Printed circuit boards 100 formed as metal-ceramic substrates, on the other hand, can dissipate the heat generated to a sufficient extent due to their increased thermal conductivity, especially compared to printed circuit boards made of base bodies 2 made of the above-mentioned materials, i.e. plastics, in particular fiber-reinforced plastics, epoxy resin and/or hard paper, but are more complex to produce and cost-intensive in terms of manufacturing technology.

In order to utilize the positive properties of a printed circuit board 100 made of a plastic, an epoxy resin or a hard paper and the positive properties of a metal-ceramic substrate, in particular its thermal conductivity, it is preferably provided that the printed circuit board 100 according to the embodiment shown in FIG. 1 has a base body 2 which extends along the main extension plane HSE and into which an insert 1 is integrated, wherein the insert 1 is provided as a metal-ceramic substrate. Preferably, it is provided that the metalceramic substrate, which is used as insert 1, is arranged in the printed circuit board 100 at such locations where increased heat generation is to be expected. For example, it is provided that the insert 1 is arranged below one or more electrical components 5 in a stacking direction S perpendicular to the main extension plane HSE in order to be able to dissipate the heat generated during operation. Preferably, it is provided that an expansion A of the insert 1 is greater than an expansion of the electrical component dimensioned parallel to the main extension plane HSE in order to guarantee effective heat dissipation.

Preferably, it is provided that at least one insert 1, preferably several inserts 1 are integrated into the base body 2 of the printed circuit board 100. A component side BS of the insert 1 ends essentially flush with a component side BS of the base body 2 and/or a backside RS of the insert 1 ends flush with the backside RS of the base body 2. Furthermore, it is preferably provided that a proportion of a volume of the insert 1 or a plurality of inserts 1 in the volume of the base body 2 or the entire printed circuit board 100 is less than 50%, preferably less than 30% and more preferably less than 15%. It has been shown that with such low proportions it is already possible to effectively improve the thermal properties of the printed circuit board 100 and at the same time to work predominantly with materials for the base body 2 that are easy to process and less cost-intensive than metal-ceramic substrates.

Preferably, it is provided that the insert 1, which ends flush with the component side BS and the backside RS of the base body 2 in a stacking direction S running perpendicular to the main extension direction HSE, interacts via a form fit with the base body 2 in a direction running perpendicular to the main extension direction HSE. This enables or supports a secure hold of the insert 1 in the printed circuit board 100. Preferably, it is provided that the selection of the materials, which might be a material of the base body 2 on the one hand or one of the materials or several materials of the ceramic element 30, is made in such a way that the differences in the thermal expansion coefficients are kept as low as possible in order to prevent thermomechanical stresses from causing cracks and/or damage to the printed circuit board 100 and/or the metal-ceramic substrate. Preferably, the thermal expansion coefficient of the insert 1 does not deviate from the thermal expansion coefficient of the base body 2 by more than 30%, preferably not more than 15% and more preferably not more than 10% of the thermal expansion coefficient of the insert 1. To select the inserts in question, the skilled person uses, for example, simulations for the respective compositions of the inserts and compares these with the values for the base body 2. In particular, it is provided that the insert 1 is cylindrical in form and/or has an essentially rectangular, in particular square, cross-section, wherein the corners are rounded.

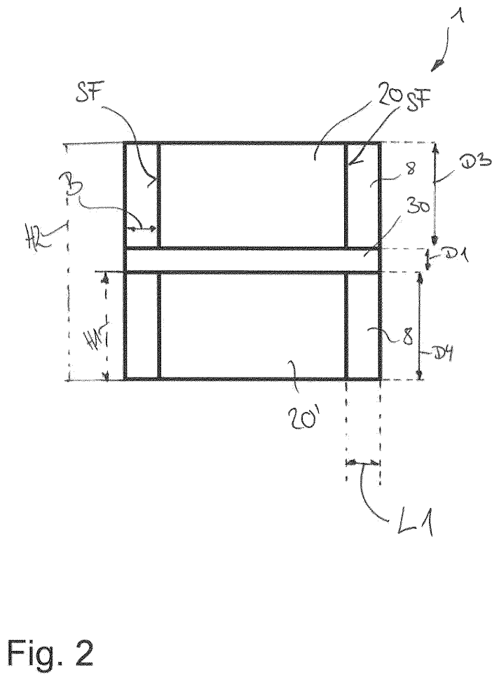

FIG. 2 illustrates an insert 1 as a first exemplary embodiment of the present invention. To form an insert, essentially formed from a metal-ceramic substrate, it is provided in particular that, in a first step, a bonding of a component metallization 20 to a ceramic element 30 takes place. The bonding of the component metallization 20 and/or the backside metallization 20′ is preferably carried out by a direct metal bonding method, such as a DCB or DAB method, by a soldering method, in particular an active soldering metal method, by a diffusion bonding process and/or by hot isostatic pressing. Bonding via a thick film technique is also conceivable. Preferably, the inserts 1 are separated from a master card, i.e. singulated.

In particular, it is provided that the insert 1 has a ceramic element 30, a component metallization 20 and a backside metallization 20′. In the assembled state, in which the insert 1 is integrated into the printed circuit board 100 or into the base body 2, the component metallization 20 faces the component side BS of the printed circuit board 100, while the backside metallization 20′ faces the backside RS. It is further provided that the ceramic element 30 has a first thickness D1, the component metallization 20 has a third thickness D3 and the backside metallization 20′ has a fourth thickness D4. Preferably, the third thickness D3 is the same size as the fourth thickness D4. However, it is also conceivable that, for example, the third thickness D3 is greater than the fourth thickness D4 or vice versa, thus advantageously allowing the ceramic element 30 to be positioned differently within the insert 1 along the stacking direction S running perpendicular to the main extension plane HSE. For example, this makes it possible to provide a thicker component metallization 20, which provides a high thermal conductivity in the area facing the component 5 due to the increased third thickness. This can prove advantageous when dissipating heat.

Furthermore, it is preferably provided that the ceramic element 30 with the first thickness D1 is dimensioned such that a ratio between the first thickness D1 and the component metallization 20 and/or a ratio of the first thickness D1 to the second thickness D2 of the base body 2 has a ratio which is between 0.01 and 0.3, preferably between 0.01 and 0.2 and more preferably between 0.01 and 0.15. As a result, a ceramic element 30 that is thin compared to the component metallization 20 and the base body 2 is used to ensure both good heat dissipation and the desired insulation strength.

Furthermore, it is provided that the ceramic element 30 projects in a direction parallel to the main extension plane HSE by a first length L1 relative to the component metallization 20 and/or the backside metallization 20′. As a result, a so-called pullback is formed on the outer circumference of the metal-ceramic substrate 1. The top side of the insert 1 facing the component side BS and the bottom side of the insert 1 facing the backside RS are joined together by means of side surfaces SF that do not run parallel to the main extension plane HSE. In the assembled state, the side surfaces SF of the metal-ceramic substrate face the base body 2 of the printed circuit board 100. In particular, the side surface SF of the metal-ceramic substrate comprises subsections of the component metallization 20, the ceramic element 30 and the backside metallization 20′.

In order to increase the insulation strength of the inserted insert 1, in particular with respect to the base body 2 of the printed circuit board 100, it is preferably provided that an insulating element 8 covers the side surface SF of the metal-ceramic substrate at least partially. By covering the side walls or side surfaces SF of the metal-ceramic substrate, the insulating element 8 is arranged between the base body 2 and the metal-ceramic substrate in the assembled state. For example, the insulating element 8 may be a coating with a corresponding insulating layer which has, for example, a width B between 10 μm and 800 μm, preferably between 150 μm and 500 μm and more preferably between 250 μm and 350 μm in a direction dimensioned parallel to the main extension plane HSE. In the embodiment example shown in FIG. 2, the insulating element 8 completely covers or surrounds the component metallization 20 and the backside metallization 20′. In particular, in the embodiment example of FIG. 2, the side surface of the ceramic element 30 is free from the insulating element 8 and the insulating element 8 extends above and below the ceramic element 30 in each case. For example, the covering element 8 is an encapsulation with a filler material, which ends flush with the outer circumference of the ceramic element 30, for example in the embodiment example of FIG. 2. The corresponding filler material is and/or contains, for example, a plastic, in particular a fiber-reinforced plastic, an epoxy resin and/or a hard paper and is particularly preferably made of the same material as the base body 2 of the printed circuit board 100. More preferably, it is provided if the filler material for the insulating element 8 has additional insulating components, such as ceramic particles, which are distributed in the filler material of the insulating element 8.

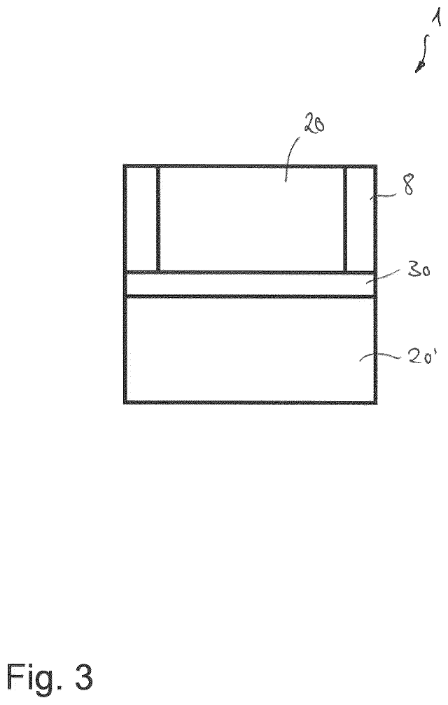

FIG. 3 shows an insert 1 according to a second exemplary embodiment of the present invention. In the embodiment example shown here in FIG. 3, the insulating element 8 is formed in such a way that it exclusively surrounds the component metallization 20, in particular via the entire height of the component metallization 20. Alternatively, it is conceivable that only the backside metallization 20′ is surrounded by an insulating element 8. In the embodiment example shown in FIG. 3, the subsection of the side surface SF of the metal-ceramic substrate in which the ceramic element 30 and the backside metallization 20′ are arranged remains essentially free of an insulating element 8.

Preferably, it is provided that the insulating element 8 extends along a first height H1 dimensioned perpendicularly to the main extension plane HSE, wherein a ratio of the first height H1 to a total height H2 of the entire insert 1 has a value between 0.4 and 1, preferably between 0.5 and 1 and more preferably between 0.7 and 1.

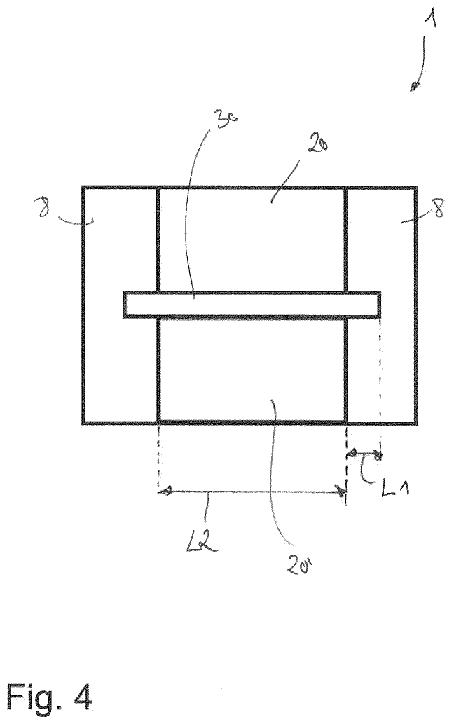

FIG. 4 shows an insert 1 according to a third exemplary embodiment of the present invention. In the embodiment shown in FIG. 4, the insulating element 8 completely surrounds the metal-ceramic substrate on its side surfaces SF. In the illustrated embodiment example, the top side and the bottom side, i.e. the outer side of the metal-ceramic substrate facing the component side BS and the outer side facing the backside RS, are free of an insulating element 8. Alternatively, it is also conceivable that the insulating element 8 additionally covers the component side BS and/or the backside RS at least partially and/or completely. Preferably, in this case at least a subregion on the component side BS is left free in order to allow corresponding connection options of a component 5 for component metallization 20.

In particular, it is provided in the embodiment example of FIG. 4 that the side surfaces SF of the ceramic element 30 are also surrounded by the insulating element 8 and thus the side surfaces SF of the metal-ceramic substrate are completely enclosed. For example, it is provided here that a first length L1 of the projecting section of the ceramic element 30 relative to a second length L2 of the component metallization 20 and/or backside metallization 20′, which is dimensioned parallel to the main extension plane HSE, has a value between 0.01 and 0.3, preferably between 0.01 and 0.2 and more preferably between 0.01 and 0.1.

Furthermore, it is conceivable that the second length L2 of the component metallization 20 differs from the second length L2 of the backside metallization 20′ (not shown).

Preferably, the component side BS and/or backside RS of the metal-ceramic substrate remain free of an insulating element 8 or a part of the insulating element 8 in order to provide corresponding connecting areas to the component side BS or to allow direct access of the cooling element to the backside metallization 20′.

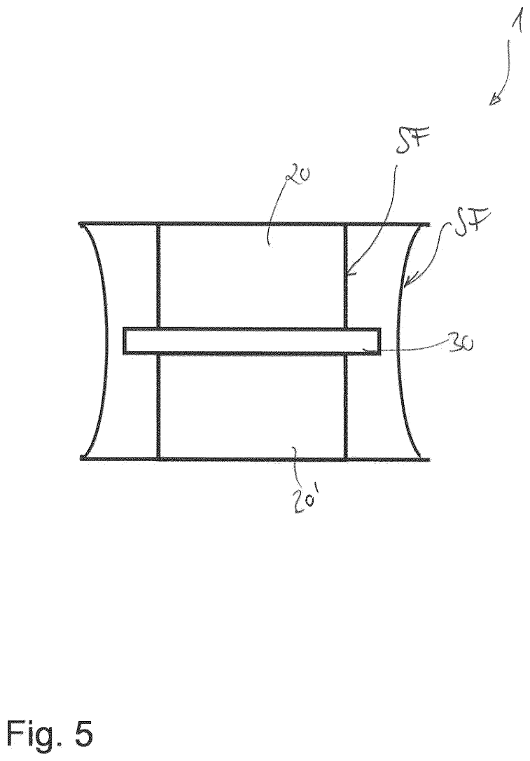

FIG. 5 shows a fourth exemplary embodiment of the present invention. Here, the embodiment in FIG. 5 essentially corresponds to that in FIG. 4, wherein the insulating element 8 has a side profiling on the side surface SF. By means of such a side profiling, it is advantageously possible to realize a form fit between the base body 2 and the insert 1, which fixes the insert 1 in the base body 2 of the printed circuit board 100 and holds it permanently. Preferably, a material bonded connection is also realized between the insert and the base body.

Furthermore, it is conceivable that in all other exemplary embodiments shown, the side surface SF of the insert 1 with insulating element 8 has a side profiling in order to thereby form a form fit with the base body 2 in a direction running perpendicular to the main extension plane HSE. For example, it is conceivable that only the insulating element 8 in the area of the component metallization 20 and/or backside metallization 20′ or the component metallization 20 and/or backside metallization 20′ has a corresponding side surface profile that is suitable for a corresponding side profiling for a form fit. It is also conceivable that the ceramic element 30 protrudes with respect to the metal layer and/or component metallization 20 and/or with respect to the insulating element 8 in a direction parallel to the main extension plane HSE, in order to thereby cause a corresponding form fit in a direction perpendicular to the main extension plane HSE.

For example, the side profiling is a concave and/or convex shaped section, which can also extend, for example, via the entire second height of the insert 1. It is conceivable that the side profiling is predetermined, for example, by the insulating element 8. It is conceivable that the side profiling is created when the insulating element 8 is formed, for example by a corresponding mold, or by subsequent processing, for example by machining. It is also conceivable that the side profiling is formed by a stepped, inclined, curved or tapered course of the insulating element 8, at least partially. It is also conceivable that the side surface SF of the insert 1 and/or of the insulating element 8 is undulated designed or forms several local maximums and minimums in the width B in order to be formed for the desired form fit.

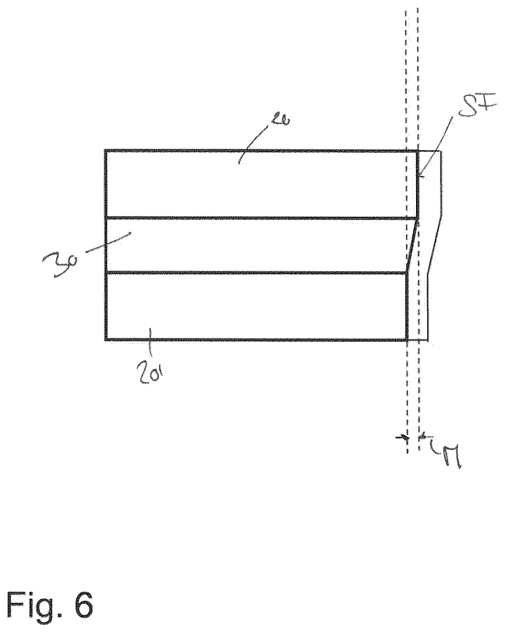

FIG. 6 shows a fifth exemplary embodiment of the present invention. This embodiment differs in that the component metallization 20 protrudes with respect to the backside metallization 20′ in order to realize a lateral surface course of the insert 1, which causes a form fit between the insert 1 and the base body 2. A modulation depth M is determined by the component metallization 20 protruding in a direction parallel to the main extension plane HSE. It can also be seen that the side surface SF of the insert 1 in the region of the ceramic element 30 has a course that is oblique with respect to the stacking direction S. Thereby, the protruding course of the side surface SF in the area of the component metallization 20 is caused. Alternatively, it is also conceivable that the backside metallization 20′ protrudes with respect to the ceramic element 30. In the example shown in FIG. 6, the courses of the side surface SF in the region of the component metallization 20 and the backside metallization 20′ are parallel to the stacking direction S. It is also conceivable that the course of the side surface SF in the region of the backside metallization 20 and/or component metallization 20′ contributes to forming the modulation depth or height. In principle, it is also conceivable that the side surfaces SF have several local maxima and/or minima in their modulation depth or height M.

In particular, it is provided in the embodiment example of FIG. 6 that the side surface SF of the metal-ceramic substrate 1 is preferably completely covered with an insulating element 8. In this case, the insulating element 8 has a substantially constant width B along the entire height. The insert 1 of FIG. 6 has a corresponding side surface profiling, since the contour of the side surface SF of the metal-ceramic substrate is also present on the outer side of the insulating element 8 due to the constant thickness or constant width of the insulating element 8. In particular, this embodiment proves to be particularly easy to manufacture, since the entire side surface SF only needs to be covered with a constant width insulating layer 8 in order to provide the desired additional insulation protection.

### REFERENCE SIGNS

1 insert
2 base body
4 conductor path
5 component
7 connection
8 insulating element
20 component metallization
20′ backside metallization
30 ceramic element
100 printed circuit board
HSE main extension plane
S stacking direction
D1 first thickness
D2 second thickness
D3 third thickness
L1 first length
L2 second length
M modulation depth
SF side surface
RS backside
BS component side
B width
H1 first height
H2 total height

1-15. (canceled)

16. A printed circuit board (100) for electrical components (5) and/or conductor paths (4), comprising
a base body (2) which extends along a main extension plane (HSE), and
an insert (1) which is integrated into the base body (2) in an assembled state,
wherein the metal-ceramic substrate (1) has a ceramic element (30), and wherein the insert (1) is a metal-ceramic substrate (10) with an insulating element (8), characterized in that the metal-ceramic substrate (1) is covered at least partially by the insulating element (8) on a side surface (SF) facing the base body (2) in the assembled state, and in that, measured in a direction running perpendicular to the main extension plane (HSE), the ceramic element (30) has a first thickness (D1) and the base body (2) has a second thickness (D2), wherein a ratio between the first thickness (D1) and the second thickness (D2) has a value between 0.01 and 0.3.

17. The printed circuit board (100) according to claim 16, wherein the metal-ceramic substrate (1) has a component metallization (20), wherein the insulating element (9) surrounds the ceramic element (30) at least partially on the sides facing the base body (2) in the assembled state.

18. The printed circuit board (100) according to claim 16, wherein the metal-ceramic substrate (1) has a component metallization (20), wherein the insulating element (9) surrounds the component metallization (20) at least partially on the sides facing the base body (2) in the assembled state.

19. The printed circuit board (100) according to claim 17, wherein the insulating element (8) covers at least partially a top side of the component metallization (20) facing away from the ceramic element (30).

20. The printed circuit board (100) according to claim 16, wherein the ceramic element (30) of the metal-ceramic substrate (10) protrudes by a first length (L1) in a direction parallel to the main extension plane (HSE) with respect to a component metallization (20) of the metal-ceramic substrate (10).

21. The printed circuit board (100) according to claim 16, wherein the insert (1) and/or the insulating element (8) cooperates via a form fit with the base body (2) in a direction perpendicular to the main extension plane (HSE).

22. The printed circuit board (100) according to claim 20, wherein the insert (1) and/or the insulating element (8) is material bonded to the base body (2).

23. The printed circuit board (100) according to claim 16, wherein in order to form the cooperation via form fit, the insulating element (8) is profiled on a side surface (SF) not running parallel to the main extension plane (HSE).

24. The printed circuit board (100) according to claim 16, wherein the insulating element (8) has, in a direction dimensioned parallel to the main extension plane (HSE), a width (B) averaged along the first height of the insulating element, which has a value between 10 μm and 800 μm.

25. The printed circuit board (100) according to claim 16, wherein the insulating element (8) has, in a direction dimensioned parallel to the main extension plane (HSE), a width (B) averaged along a first height of the insulating element (8), which has a value greater than 250 μm.

26. The printed circuit board (100) according to claim 16, wherein dimensioned in a direction perpendicular to the main extension plane (HSE) the component metallisation (20) has a third thickness (D3), wherein a ratio between the first thickness (D1) and the third thickness (D3) has a value between 0.01 and 0.3.

27. A metal-ceramic substrate (10), which is configured as an insert (1) for a printed circuit board (100) according to claim 16, wherein the insert (1) is surrounded at least partially by an insulating element (8) on a side surface (SF) not running parallel to the main extension plane.

28. The metal-ceramic substrate (10) according to claim 27, wherein the insert (1) is completely surrounded by an insulating element (8) on the side surface (SF) not running parallel to the main extension plane.

29. The metal-ceramic substrate (10) according to claim 27, wherein the insulating element (8) surrounds the metal-ceramic substrate (10) in an enclosed manner at least in a height portion of the metal-ceramic substrate (10).

30. A method of manufacturing a printed circuit board (100) according to claim 16, comprising:
providing a metal-ceramic substrate (10) having a main extension plane (HSE),
covering the metal-ceramic substrate (1) at least partially with an insulating element (8) in order to form the insert, and
inserting the insert with the insulating element into the base body (2).
